(19) United States
(12) Patent Application Publication
(10) Pub. No.: US 2010/0267567 A1
(43) Pub. Date: Oct. 21, 2010

(54) SUPERCONDUCTING MAGNET SYSTEM WITH COOLING SYSTEM

(75) Inventors: Johannes Adrianus Overweg, Uelzen (DE); Holger Timinger, Hamburg (DE); Bernd David, Huettblek (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/746,778

(22) PCT Filed: Dec. 3, 2008
(86) PCT No.: PCT/IB2008/055065

§ 371 Date: Jun. 8, 2010

(30) Foreign Application Priority Data
Dec. 10, 2007 (EP) 07122698.9

(51) Int. Cl. H01F 6/04; G01R 33/3815

(52) U.S. Cl. 505/163; 335/216

(57) ABSTRACT

A magnet system, in particular for a magnetic resonance examination system, comprises a superconductive main magnet having a near group of coil windings and a remote group of coil windings. A gradient coil system forms a source of power dissipation into at least part of the coil windings. The near group of coil windings and the remote group of coil windings are near and remote from the source of power dissipation, respectively A cooling system has a high-temperature cooling station and a low-temperature cooling station. The high-temperature cooling station cools mainly the near group of coil windings. The low temperature cooling station cools mainly the remote group of coil windings. The near and remote group optionally are made of different superconductive materials. Thus, additional degrees of freedom are achieved which allow less expensive magnet design.

### FIELD OF THE INVENTION

The invention pertains to a superconducting magnet with a cooling system.

### BACKGROUND OF THE INVENTION

The U.S. Pat. No. 6,396,377 shows a superconducting magnet assembly with individual magnetic coils in vacuum jackets. Each magnet coil is cooled to superconducting temperature by direct coupling to a two stage closed cycle refrigerator. The closed cycle refrigerator operates as a cooling system. In particular the two stage refrigerator produces about 50K at the first stage and liquid He temperature or about 4K at the second stage.

### SUMMARY OF THE INVENTION

An object of the invention is to further improve the efficiency of cooling of the magnet coils.

This object is achieved by the magnet system of the invention comprising
a superconductive main magnet having a near group of coil windings and a remote group of coil windings
a source of power dissipation into at least part of the coil windings
   the near group of coil windings and the remote group of coil windings being near and remote from the source of power dissipation, respectively
a cooling system having a high-temperature cooling station and a low-temperature cooling station
   the high-temperature cooling station cooling mainly the near group of coil windings and
   the low temperature cooling station cooling mainly the remote group of coil windings.

The invention is based on the insight that cooling is generally more efficient at higher temperature and that cooling to a very low temperature is not always required. Of course, both the high-temperature and the low-temperature are below the critical temperature for superconductivity for the material of the coil windings. In particular the relatively higher temperature allowing efficient cooling is applied near the source of power dissipation and cooling to lower temperatures is applied more remotely from the source of power dissipation. Often coil windings further away from the source of power dissipation are located near the ends of magnet system (in case of cylindrical magnets) or at a large diameter (in case of superconducting vertical field magnets) where the magnetic field is strong and has a substantial radial component relative to the main axis of rotational symmetry of the magnet system. Because the coil windings near the ends of the magnet system are cooled to a lower temperature it is achieved that the critical current is increased so that a smaller amount of the expensive conductor material is sufficient to ensure that the critical current (density) is not exceeded and the coil windings remain superconductive. On the other hand, the coil windings closer to the source of power dissipation are often located near the centre of the magnet system where the magnetic field is smaller and is directed substantially along the axis of rotational symmetry of the magnet. Under these conditions, the critical current of high temperature superconductors is relatively high even at higher temperatures and operation at a higher temperature does not lead to a dramatic increase in conductor cost.

In order to support temperature differences between the near group of coil windings and the remote group of coil windings, the near and remote groups of coil windings are thermally isolated by the thermal resistance. In particular the thermal resistance is form by a common glass-fibre plastic support structure.

In one aspect of the invention the magnet system is employed in a magnetic resonance examination system.

These and other aspects of the invention will be further elaborated with reference to the embodiments defined in the dependent Claims.

In order to apply gradient magnetic fields for spatial encoding of magnetic resonance signals and also for spatial selectivity of RF fields, gradient coils are provided.

In one aspect of the invention the magnetic fields generated by the gradient coil system are allowed to penetrate the windings of the main field magnet belonging to the near group while the gradient-related magnetic fields are small at the position of the main magnet sections belonging to the remote group. When the gradient coils are switched to apply gradient pulses, i.e. temporary magnetic gradient fields, AC losses occur in the superconducting material of the coil windings of the near group. Thus, the gradient coils act as the source of power deposition. According to the invention, the coil windings which are exposed to the gradient fields are cooled more efficiently by operating these at a higher temperature where refrigerators generally have a high efficiency. The coil windings which are more remote from the gradient coils and are not exposed to significant gradient-related magnetic fields are cooled by the low-temperature cooling station to a lower temperature, which improves the critical current, i.e. allows a higher critical current, in the superconducting material and leads to a reduction in the amount of superconducting wire required to generated the main field. In a practical embodiment, the high- and low-temperature cooling stations are thermal interfaces of a single multi-stage refrigerator.

Thus, the invention circumvents the need to avoid power deposition by the gradient coils into the coil windings of the superconductive main magnet. Notably the invention enables that the gradient coils can be located radially outside of the coil windings. A magnetic resonance examination system having the gradient coils located radially outside of the coil windings is described in the international application PCT/US2006/61914. In the region outside of the main coil windings there is only a low magnetic field strength only due to the return flux. Hence, when the electrical current through the gradient coil is switched, at most a weak Lorentz force acts on the windings of the gradient coil and at the acoustic noise generated by the gradient coils is low. When the gradient coils are positioned outside of the main coil windings, there is no need to provide space within the main coil windings for the gradient coils. Accordingly, the diameter of the main coil windings may be reduced e.g. to 0.7 m, whereas conventional MRI magnets with a separate gradient coil in the warm bore have a winding diameter of approximately 0.95 m. To first approximation, the amount of superconducting material required for a cylindrical MRI magnet increases with the square of its diameter. As a consequence, the amount of the superconductive conductors of windings of the main magnet coil can be reduced, so that less of the relative expensive superconducting material is needed. Alternative to a gradient coil system on the outside of the magnet, a very thin unshielded gradient coil can be placed inside the main magnet, either directly inside the main magnet windings or on the warm bore tube of the cryostat. In all of these cases the central sections of the main magnet will be exposed to significant gradient-related magnetic fields leading to significant losses in these coil sections.

In a particular example of the invention, the high-temperature cooling station has a cooling power in the range of 100-200 W and an operating temperature in the range of 45-75K. The low-temperature cooling station has a cooling power in the range of 10-15 W and an operating temperature in the range of 25-40K. This arrangement is suitable to cool the coil windings of the superconductive main magnet wound from a high-temperature superconductor such as Yttrium Barium Copper Oxide (YBCO) manufactured by deposition of the superconducting material as a thin film on a metallic tape substrate. The central sections of the coil are exposed to a static field of approximately 1.5 Tesla, directed mainly parallel to the superconducting tape. Under these conditions, a reasonable critical current is obtained at a temperature of 60-65K. The end coils of the magnet are exposed to a much stronger static field (3-5 T), which has a component directed perpendicular to the superconducting tape in some regions of the coil section. Under these conditions, the critical current at a temperature of 60K would be very small. A much higher critical current is obtained when these sections of the magnet are cooled to a temperature between 30 and 40 K. This higher critical current allows the total amount of conductor used in the end coils of the magnet to be reduced by a significant factor compared to the case when all coils would be operated a the temperature level of the central coils. The optimum operating temperature can be found by seeking a cost optimum between refrigeration costs (which increase on reducing the operating temperature of the coil) and conductor costs (which go down on reducing the operating temperature).

In one aspect of the invention, the end coils of the magnet are wound from a different class of high-temperature superconducting material, typically Magnesium di-Boride (MgB₂), differing from the material used in the central sections in that this material has a much lower useful operating temperature but may be an order of magnitude cheaper than the material used in the central sections (typically Yttrium Barium Copper Oxide (YBCO)).

Alternative to YBCO tape, the end coils of the dual-temperature magnet may be manufactured from a superconducting material such as Magnesium Diboride (MgB₂). In the current state of development, the maximum practical operating temperature in fields typically encountered in a high-field MRI magnet is about 20K. Such a low operating temperature requires a more expensive cryogenic refrigeration system, but this additional cost may be offset by the fact that the cost of MgB₂ is typically an order of magnitude lower than that of second generation YBCO tape.

In another aspect of the invention, one or more heat pipes are employed to provide a thermal connection between the cooling station(s) and the main magnet coils. Heat pipes contain a cooling medium, for example nitrogen (N₂) gas or a noble gas such as Neon. At one end (called the condenser) the heat pipe is thermally connected to the cooling station (of the refrigerator), which extracts heat from the heat pipe. The opposite end of the heat pipe is connected to the thermal load, which may be a section of the superconducting main field coil or another part of the magnet system from which heat is to be removed. This cooling end of the heat pipe can absorb heat. Heat transport between the cooling end and the condenser end takes place through evaporation of the cooling medium a the cooling end and re-condensation of the cooling medium at the condenser end. The temperature of the cooling station a the condenser end must low enough that the cooling medium condenses there. The heat pipe(s) are arranged such that the condensed cooling medium drips down from the refrigerated end to the opposite condenser end. The heat pipe may be positioned at any angle or may be curved, provided that the path of the condensed liquid between the condenser and the cooling end is downward along the entire length of the heat pipe.

Heat pipe technology per se is described in the book heat pipe science and technology [A. Faghri. 1995]. The heat pipe(s) can be made from tube material with a low thermal conductivity such as stainless steel. Alternatively a bypass of a material with a high thermal conductivity can be added to reduce the thermal resistance under operating conditions where the gas in the heat pipe is not in the gas/liquid two-phase state required for efficient heat transfer. Examples of such operating conditions occur during cool-down, when the condensing temperature has not been reached, during thermal overload when all liquid has boiled away from the heat absorbing end or when the temperature of the refrigerator is too low so that the working liquid freezes solid at the condenser.

In another aspect of the invention the coil windings of the main magnet are mounted on a glass-fibre plastic construction. In order to operate parts, e.g. sections of windings of the main field coil at a higher temperature than other parts of the main magnet, the structure holding the coil assembly together needs to have a sufficiently high thermal resistance, otherwise the temperatures of all coil sections would quickly become equal. It is estimated that a glass-fibre support structure with a thickness of 30 mm (which is sufficient to withstand the magnetic forces between the coil sections) and a length of 100 mm has a thermal resistance of approximately 5K/W. This is sufficiently low to allow operation of the end coils of the magnet at a temperature 30-40K below the central coils without creating an unacceptable conduction heat burden on the low-temperature station of the refrigerator. In order to reduce the radiation heat load on the remote group of windings, they may be surrounded by a radiation screen which is thermally anchored to the cooling station cooling the near group of windings. The entire cold mass, comprising the near group of windings, the remote group of windings, the interconnecting structures and optionally the gradient generating system, is surrounded by an electrically non-conducting vacuum enclosure. The structure holding the cold mass in position inside this vacuum enclosure is preferably attached to cold mass at the temperature level of the near group of windings.

In a further aspect of the invention the cooling system also cools the gradient coil(s). This is required if the gradient coil system is part of the cold mass. The windings of the gradient coil system may consist of a normal conducting or a superconducting material. If the gradient coils are made of copper, the resistance at 60-70K will be roughly 1/7^{th} of the room-temperature value. This results in a sufficiently low dissipation that the heat can be absorbed by the higher temperature station of the refrigerator. Alternatively the gradient windings may be made from a high-temperature superconducting material such as YBCO tape. Alternatively, the high-temperature cooling station cools the gradient coils to below their superconducting temperature. This enables that superconducting gradient coils are employed in the magnetic resonance examination system. In this aspect of the invention, the gradient coils can be thermally connected to the high-temperature cooling station by way of heat pipes. These heat pipes are thermally connected to the windings of the gradient coils at the evaporator end of the heat pipe. The refrigerated end is thermally connected to the high-temperature cooling station.

In another aspect of the invention the low-temperature cooling station has a low-power operating mode. In the low-power operating mode shutdown of the low-temperature cooling station is shut down and/or the cooling power is reduced of the high-temperature cooling station when the MRI system is not in use. When the magnetic resonance examination system is not scanning, the low-temperature cooling station can be switched to the low-power operating mode in which power is saved, but the temperature increases of the remote group of coils.

In general terms, the features of the present invention provide additional degrees of freedom which allow less expensive magnet design and improved performance.

### BRIEF DESCRIPTION OF TH DRAWINGS

These and other aspects of the invention will be elucidated with reference to the embodiments described hereinafter and with reference to the accompanying drawing wherein

FIG. 1 shows a schematic representation of an example of a magnet system for a magnetic resonance examination system in which the invention is employed;

FIG. 2 shows a schematic representation of another example of a magnet system for a magnetic resonance examination system in which the invention is employed;

FIG. 3 shows an example of the dependence of the cooling power as a function of temperature of the cooling station employed in a magnet system of the invention and

FIG. 4 shows typical graphs of the critical current of a high-temperature superconductor such as YBCO as a function of the field parallel or perpendicular to the conducting tape, for two typical operating temperatures.

### DETAILED DESCRIPTION OF THE PREFERRED EMBODIMENTS

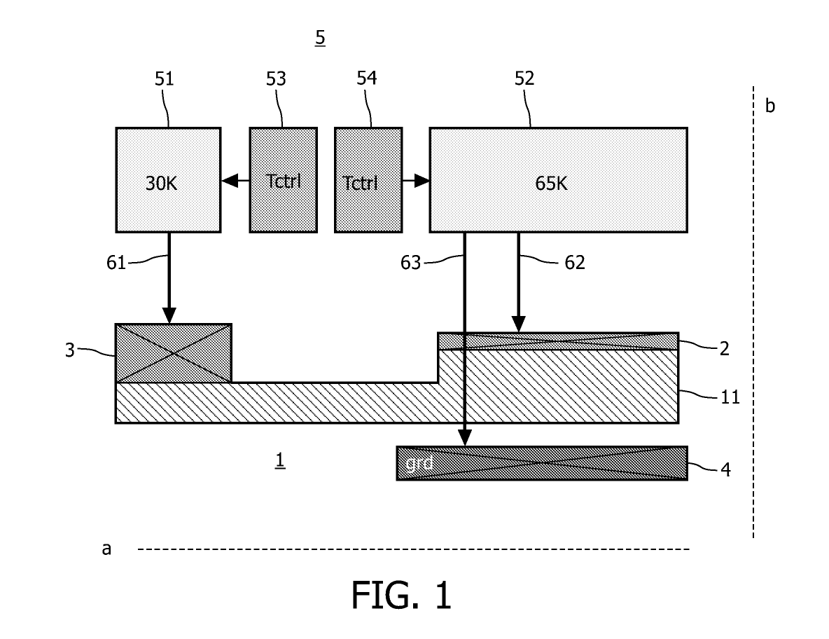

FIG. 1 shows a schematic representation of a magnet system for a magnetic resonance examination system in which the invention is employed. The magnet system comprises a set 1 of main field coils including a central magnet coil 2 and an end coil 3. Because the set of main field coils is symmetric only part of the coils are actually shown in the Figure. The set of main field coils is cylindrically symmetric around its longitudinal axis a. Further the set of main field coils is reflection symmetric with respect to the symmetry plane b, which is orthogonal to the longitudinal axis a. The central magnet coil 2 is located in the centre region of the magnet system, i.e. in the centre portion of the bore of the cylindrical magnetic resonance examination system when the magnet system is incorporated in the magnetic resonance examination system. The end coil 3 is located at the end of the bore of the cylindrical magnetic resonance examination system. In practice several central coils and several end coils may be employed. The central coils and the end coils, when energised, co-operate to form a homogeneous static magnetic field (the main field) in the bore of the magnetic resonance examination system of typically 1.5 T, 3.0 T or 7.0 T. A gradient coil system 4 is provided, which when energised, produces a gradient magnetic field (gradient field) superposed on the main field. In practice several gradient fields are applied in several, usually orthogonal, directions to achieve spatial encoding of the magnetic resonance signals. The gradient coils are operated in a pulsed fashion, i.e. they are intermittently switched on and off to produce the temporary gradient magnetic fields for selective excitation, for phase encoding and for read encoding of the magnetic resonance signals. In the magnet/gradient systems considered here, the fields generated by the gradient coil are allowed to penetrate into the windings of the central sections of the main magnet (in conventional MRI systems, the gradient magnetic fields do not reach the main magnet coils). This AC field exposure of the main magnet windings leads to eddy-current and hysteresis losses. In the example shown here the gradient coil 4 gives rise to power deposition mainly in the central coil 2 and (to a much lesser degree) also in the end coil 3.

The main field coils 2,3 are superconducting coils and they are cooled by the cooling system 5 that is coupled to the coils by way of several heat pipes 61,62. The cooling system includes the high-temperature cooling station 52 which is coupled by the heat pipe 62 tot the central coil 2 and operates at a temperature of 65K. The cooling system also includes the low-temperature cooling station 51 coupled with the heat pipe 61 to the end coil 3 and operates at temperature of 30K. The high-temperature cooling station 52 and the low-temperature cooling station 51 are regulated by temperature control modules 53 and 54. This enables to independently control the temperatures of the central and end coils 2,3 respectively.

The gradient coil can also be a superconductive coil which is cooled by the high-temperature cooling station 52. To this end a heat pipe 63 is provided to thermally connect the gradient coil 4 to the high-temperature cooling station 52. In the example shown in FIG. 1 the gradient coil is located at the inside of the main field coils. Note that each of the heat pipes 61, 62, 63 may in reality consist of a plurality of heat pipes connected in parallel and attached to several heat transfer stations on the structures to be cooled.

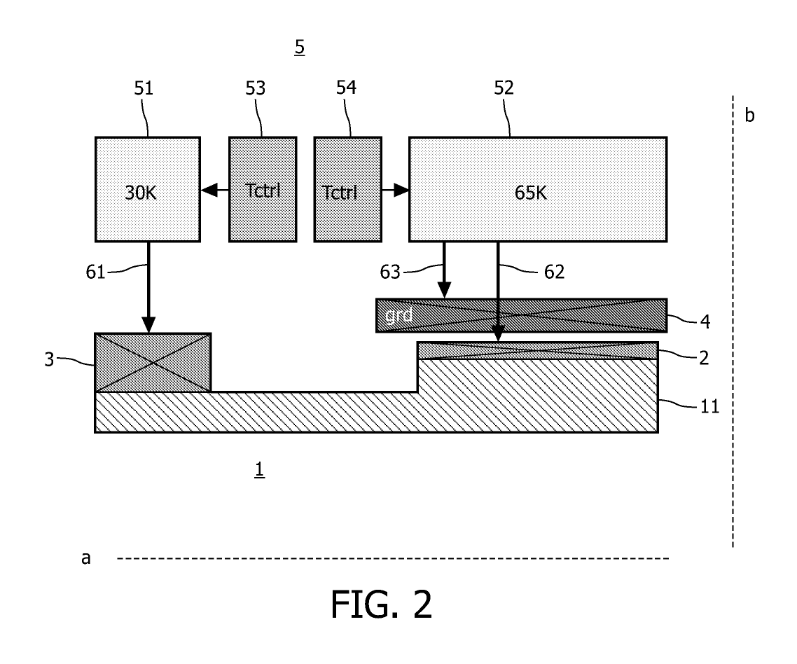

FIG. 2 shows a schematic representation of another example of a magnet system for a magnetic resonance examination system in which the invention is employed. In particular in the example of FIG. 2 the gradient coil(s) are located outside of the main field coils, i.e. the gradient coil(s) are located at the side of the main field coils remote from the longitudinal axis a. In this way less radial bore space is taken up the gradient coil(s) so that the patient to be examined experiences to a lesser extent to be locked in when in the bore of the magnetic resonance examination system. Moreover, as the gradient coil is located outside of the main field coils, the gradient coil is in a region where there is at most of low magnetic field and thus the gradient coil generates a low level of acoustic noise when the gradient coil is switched.

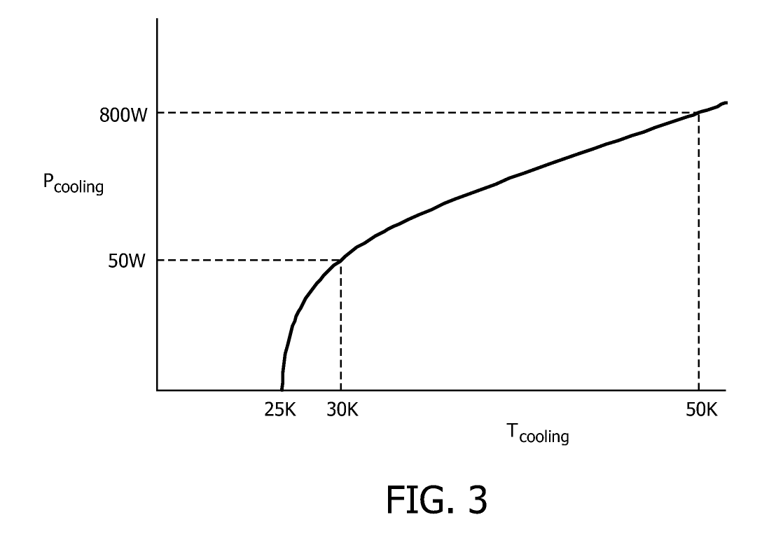

FIG. 3 shows an example of the dependence of the cooling power as a function of temperature of the cooling station employed in a magnet system of the invention. As is apparent from FIG. 3, the cooling power of the cooling station increases with increasing temperature, notably at low temperatures in the range of 25K to 30K the cooling power drops rapidly as the temperature is decreased. Higher cooling efficiencies are achieved at temperatures of about 50K. Depending on details of the construction of the refrigerator, the minimum temperature obtained at zero heat load and the temperature as a function of applied heat load may differ from the curve shown in FIG. 3, but the general shape will be similar, resulting in a rapid increase in available cooling power if a higher working temperature is selected. The two cooling stations shown in FIGS. 1 and 2 may correspond to two physically separate refrigerators or they may be two cooling stages on a single multi-stage refrigerator. In the latter case, each of the cooling stages of the multi-stage refrigerator can be characterized by a load curve having the general shape as shown in FIG. 3.

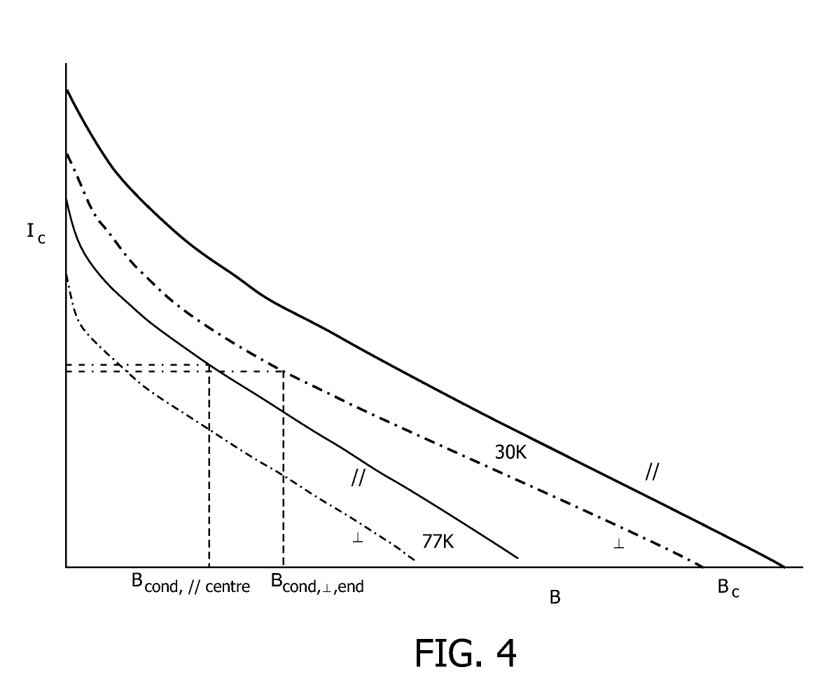

FIG. 4 shows the typical dependence of the critical current (density) I_{c} of a second generation YBCO tape conductor as a function of magnetic field strength B (parallel to or perpendicular to the plane the tape) for two different temperatures. In general, the critical current decreases with increasing magnetic field strength and/or increasing temperature. The critical current is higher when the field to which the conductor is exposed is oriented parallel to the surface of the tape.

The FIG. 4 contains two operating points for conductor used in two different sections of the superconducting magnet. The first point corresponds to the central section, operated at a relatively high temperature, where the field acting on the conductor is smaller and directed predominantly parallel to the tape surface. The current in this coil section is limited by the 77K I_{c}(B)_{//} curve. The other point corresponds to the conductor in the lower temperature end coil, where the field is larger and directed perpendicular to the tape in parts of the coil. This coil can be operated at currents up to the 30K I_{c}(B)_{⊥} curve. It is clear that if the end coil would also be operated at the higher temperature, the maximum current would be limited by the 77K I_{c}(B)_{⊥} curve, which is a much lower value. In order to enable superconducting operation, the number of turns for a 77K end coil would have to be many times higher than for the 30K operating temperature. Hence, at lower temperatures less coil windings are required to generate a given main magnetic field strength. That is, less expensive superconductor material is required. On the other hand, as is apparent from FIG. 3, cooling power at lower temperatures is less, so the low operating temperature can only be used in parts of the magnet system where the gradient-related dissipation is small. Even for low dissipation conditions the cost of refrigeration equipment and cryogenic insulation increase with decreasing temperature and there will therefore exist an optimum working temperature at which the combined cost of the superconducting material and the cryogenic cooling reaches a minimum.

The present invention provides the capability of finding a compromise between on the one hand cooling at a low temperature, notably for the coil windings that experience a relatively high transverse (to the plane of the strip conductor) magnetic field component which provides a sufficient acceptable current density so that only a moderate number of coil windings is needed and on the other hand more efficient cooling at higher temperatures where the maximum current at which superconductivity is sustained is higher. The critical current for magnetic fields transverse to the plan of the strip-like conductor determines the maximum current at which superconductivity is sustained. Magnetic fields transverse to the plane of the strip-like conductor are dominated by the transverse magnetic field component at the end coils 3. When cooling is performed to lower temperature, e.g., to 30K the acceptable current (density) increases from I_{T=77} at 77K to I_{T=30} at 30K. At the centre coil the acceptable current density at which superconductivity is sustained is determined by the in-plane component of the magnetic field strength. The Figure shows that at the relatively high temperature of e.g. 77K the in-plane critical current is still somewhat higher than current density I_{T=30}. At the higher temperature of e.g. 77K the maximum current density that sustains superconductivity in the centre coil 2 is still somewhat higher than that in I_{T=30} the end coil. The in-plane component of the main magnetic field at the centre coil allows a relatively high current density while sustaining superconductivity. The transverse component at the centre coil is only marginal and therefore corresponds to a high allowable current density.

1. A magnet system, in particular for a magnetic resonance examination system, comprising
a superconductive main magnet having a near group of coil windings and a remote group of coil windings
a source of power dissipation into at least part of the coil windings
the near group of coil windings and the remote group of coil windings being near and remote from the source of power dissipation, respectively
a cooling system having a high-temperature cooling station and a low-temperature cooling station
the high-temperature cooling station cooling mainly the near group of coil windings and
the low temperature cooling station cooling mainly the remote group of coil windings.

2. A magnet system as claimed in claim 1, comprising (a) gradient coil(s) to apply a magnetic gradient field wherein the near group of coil windings is near the gradient coil(s) and the remote group of coil windings is remote from the gradient coil.

3. A magnet system as claimed in claim 1, wherein
the high-temperature cooling station has a cooling power in the range between 100-200 W and having an operating temperature in the range 45-75K and/or
the low-temperature cooling station has a cooling power in the range between 10-15 W and having an operating temperature in the range 25-35W.

4. A magnet system as claimed in claim 1, wherein (a) heat pipe(s) provide a thermal connection between at least one of the cooling station and its respective coil windings.

5. A magnet system as claimed in claim 1, wherein the near coil windings and the remote coil windings are thermally isolated from each other.

6. A magnet system as claimed in claim 2, wherein the cooling system is also arranged to cool the gradient coil(s).

7. A magnet system as claimed in claim 1 in which the low-temperature cooling station has a low-power operating mode.

8. A magnet system as claimed in claim 1, in which the windings of both the near coil windings and the remote coil windings are made from the same high-temperature superconducting material, in particular second generation YBCO tape.

9. A magnet system as claimed in claim 1, in which the superconductive material of the windings of the remote group is different from the superconductive material the near group and the useful operating temperature of the superconductive material of the windings of the remote group is lower than the useful operating temperature of the superconductive material of the near group.

10. An magnetic resonance examination system which comprises a magnet system as claimed in claim 1.
